(19) United States
(12) Patent Application Publication
(10) Pub. No.: US 2026/0317540 A1
(43) Pub. Date: Oct. 15, 2026

(54) THERMOSETTING COMPOSITION, PREPREG INCLUDING SAME, AND HIGH-FREQUENCY CIRCUIT BOARD

(71) Applicant: DOW TORAY CO., LTD., Shinagawa-Ku, Tokyo (JP)

(72) Inventors: Takuya OGAWA, Ichihara-shi, Chiba (JP); Yuki YONEGUCHI, Ichihara-Shi, Chiba (JP); Tomohiro IIMURA, Ichihara-shi, Chiba (JP)

(21) Appl. No.: 19/485,630

(22) PCT Filed: May 14, 2024
(86) PCT No.: PCT/JP2024/017762

§ 371 Date: Nov. 18, 2025

(30) Foreign Application Priority Data
May 19, 2023 (JP) 2023-083043

(51) Int. Cl. C08L 71/12; H05K 1/02; H05K 1/03

(52) U.S. Cl. CPC C08L 71/126; H05K 1/0237; H05K 1/0366; C08L 2203/20; C08L 2205/02

(57) ABSTRACT

Provided is a thermosetting composition that cures upon heating to provide a cured product having excellent dielectric properties, transparency, molding processability, heat resistance, and toughness. The thermosetting composition also allows for a wide range of adjustment of physical properties. Uses of the thermosetting composition and cured product are also provided. The thermosetting composition comprises: (A) a siloxane compound selected from (a1) a linear siloxane having two alkenyl groups and an aryl group and (a2) a siloxane having two alkenyl groups and having 8 or less silicon atoms; (B) an aromatic polymer/cycloolefin polymer having a reactive functional group; and (C) a thermal radical initiator.

### TECHNICAL FIELD

The present invention relates to a thermosetting composition that contains a specific siloxane compound having a reactive functional group and an aromatic polymer and that can be cured by heating. A cured product obtained from the thermosetting composition of the present invention has excellent dielectric properties, particularly low relative dielectric constant and dielectric loss tangent, and high modulus of elasticity at high temperatures, resulting in excellent heat resistance. These excellent properties make it suitable as a material for next-generation high-frequency circuit boards and as a material for coating agents for electric and electronic devices that require high insulation and heat resistance.

### BACKGROUND ART

Due to high heat resistance and excellent chemical stability, silicone resins have been used as coating agents, potting agents, insulating materials, and the like for electronic and electrical devices. Of these silicone resins, many heat-curable silicone compositions containing reactive organopolysiloxanes have been reported.

In recent years, the remarkable progress in information network technology has made it necessary to transmit and receive large volumes of information at high speed while maintaining high quality, and electronic apparatuses are being required to have faster processing speeds. In addition to the 5G (fifth generation mobile communications system) technology that has already been introduced, with an eye on future 6G technology, signals are becoming shorter in wavelength and higher in frequency in order to transmit large volumes of digital signals at high speeds. In these high frequency regions, the effect of dielectric loss on signal degradation is significant, and thus the dielectric loss of an insulating material must be reduced. Many resin materials with lower dielectric loss have been proposed as alternatives to the currently used epoxy resin. Of these, polyphenylene ether (hereinafter abbreviated as “PPE”) resin has excellent dielectric properties, such as a relative dielectric constant, dielectric loss tangent, and the like, and has high heat resistance, and therefore is widely considered as an insulating material for a circuit board of electric and electronic devices that utilize high frequency regions. (For example, Patent Documents 1 to 3)

PPE resin compositions that take advantage of the reactivity of silicon atom-bonded alkenyl groups are also being investigated. Patent Document 4 discloses a curable resin composition containing a terminally modified PPE having a vinylsilyl group at an end and a silicon-free crosslinking auxiliary agent. Furthermore, Patent Documents 5 and 6 each disclose: a polyphenylene ether resin composition containing a vinyl-modified polyphenylene ether resin and an unsaturated double bond-containing organosilicone resin having a three-dimensional network structure; and a high-frequency circuit board applying the same.

Cured products obtained from either composition have excellent dielectric properties, such as dielectric loss tangent, heat resistance, and the like. However, these cured products are characterized by high brittleness or low hardness, and adjustment of the mechanical properties thereof is not easy. Furthermore, with regard to compositions containing terminally modified PPE, manufacturing of the modified polymer is complicated, posing a problem in terms of cost.

In other words, although a cured product made of a reactive PPE and an organic crosslinking agent and having excellent dielectric properties and heat resistance has been disclosed, it is difficult to say that a thermosetting composition and a cured product thereof, which satisfy both the dielectric properties and molding processability and in which the physical properties thereof can be adjusted over a wide range, have been sufficiently disclosed.

### RELATED ART DOCUMENTS

### Patent Documents

Patent Document 1: Japanese Unexamined Patent Application 2015-44934
Patent Document 2: WO2019-130735
Patent Document 3: Japanese Unexamined Patent Application 2021-31612
Patent Document 4: Japanese Unexamined Patent Application 2023-12895
Patent Document 5: Japanese PCT Application 2018-521210
Patent Document 6: Japanese Unexamined Patent Application 2018-521211

### SUMMARY OF THE INVENTION

### Problem to be Solved by the Invention

An object of the present invention is to solve the abovementioned problems, and provide: a thermosetting composition which, upon heating, provides a cured product having excellent dielectric properties, and particularly a low relative dielectric constant and dielectric loss tangent, as well as excellent transparency, molding processability, heat resistance, and toughness, and which further allows for a wide range of adjustment of physical properties; and a use thereof.

### Means for Solving the Problem

The present invention was made to solve the abovementioned problems, and was completed on the basis of discovery that a thermosetting composition containing a siloxane compound, which contains a plurality of alkenyl groups and has a prescribed structure, and at least one compound selected from aromatic polymers having a reactive functional group and a cycloolefin polymer having a reactive functional group, provides a cured product having low dielectric properties, and particularly a low relative dielectric constant and dielectric loss tangent, as well as excellent heat resistance and toughness, and further that the thermosetting composition can adjust the physical properties of the cured product over a wide range.

Note that the aromatic polymer having a reactive functional group and the cycloolefin polymer having a reactive functional group according to the present invention are preferably polymers that have a reactive functional group but have a low polar group concentration and a low relative dielectric constant and dielectric loss tangent. From the perspective of technical effect, PPE having a reactive functional group is particularly preferred.

More specifically, the present invention is a thermosetting composition containing
(A) 10 to 90 parts by mass of one or more type of siloxane compound selected from the following (a1) and (a2):
(a1) a linear siloxane having at least two alkenyl groups and at least one aryl group in a molecule; and
(a2) a siloxane having at least two alkenyl groups in a molecule and having 8 or less silicon atoms,
(B) 10 to 90 parts by mass of at least one compound selected from aromatic polymers having a reactive functional group and cycloolefin polymers having a reactive functional group
(provided that the sum of component (A) and component (B) is 100 parts by mass), and
(C) a thermal radical initiator at an amount of 0.1 to 5 parts by mass with respect to 100 parts by mass of the total of components (A) and (B).

The abovementioned component (B) may be PPE having a reactive functional group at a molecular chain end.

The abovementioned component (B) may be PPE having one or more type of a reactive functional group selected from alkenyl groups and (meth)acrylate groups, at a molecular chain end.

The abovementioned component (A) is preferably a compound that satisfies at least one of the following conditions (a3) and (a4):
(a1-1) a linear siloxane having at least two alkenyl groups in a molecule, and in which the molar fraction of aryl groups in all substitution groups on silicon atoms is 20% or more (a2-1) a cyclic siloxane having at least two alkenyl groups in a molecule and having 8 or less silicon atoms

The thermosetting composition of the present invention may further contain (D) an organic solvent. Note that the amount of component (D) may be in the range of 10 to 1000 parts by mass with respect to 100 parts by mass of the total of components (A) to (C).

The present invention further provides a cured product of the abovementioned thermosetting composition. Furthermore, the present invention provides a prepreg including: the abovementioned cured product of the thermosetting composition; and a fibrous reinforcing material.

The present invention further provides a high-frequency circuit board including a laminate of one or more of the abovementioned prepreg.

Furthermore, the present invention further provides a method for curing and molding a thermosetting composition, the method at least including:
step (i): a step for removing component (D) from a thermosetting composition containing component (D) at a temperature in the range of approximately 80 to 100° C. under ambient pressure or reduced pressure; and
step (ii): a step for, following step (i), curing the thermosetting composition at a temperature of 150° C. or higher and then processing into a desired shape.

The present invention further provides a method for manufacturing a prepreg, the method including a step for impregnating the abovementioned thermosetting composition containing component (D) with a fibrous reinforcing material, then removing component (D) and curing the thermosetting composition.

### Effect of the Invention

The thermosetting composition of the present invention contains, as main components: a siloxane compound containing a plurality of alkenyl groups and having a prescribed structure; and at least one compound selected from aromatic polymers having a reactive functional group and cycloolefin polymers having a reactive functional group. The affinity between these two components is favorable, and therefore, the transparency and molding processability of the curable composition and a heat-cured product obtained by removing the organic solvent are particularly favorable. Furthermore, the cured product has excellent toughness and allows for a wide range of composition design, and therefore, the adjustability of the physical properties of the cured product is favorable. In addition, the cured product obtained by the present invention has favorable heat resistance and a very high modulus of elasticity even at a high temperature of 200° C. or higher. Furthermore, the cured product obtained by the present invention has a low relative dielectric constant and dielectric loss tangent, and has excellent dielectric properties. Therefore, the thermosetting composition according to the present invention is useful as an insulating material for circuit boards of devices for transmitting large volumes of digital signals at high speed, and particularly electric and electronic devices that utilize high frequency regions.

### DESCRIPTION OF THE PREFERRED EMBODIMENTS

A configuration of the present invention will be further described in detail below. The thermosetting composition of the present invention contains, as essential components,
(A) one or more type of siloxane compound selected from the following (a1) and (a2):
(a1) a linear siloxane having at least two alkenyl groups and at least one aryl group in a molecule; and
(a2) a siloxane having at least two alkenyl groups in a molecule and having 8 or less silicon atoms,
(B) at least one compound selected from aromatic polymers having a reactive functional group and cycloolefin polymers having a reactive functional group, and (C) a thermal radical initiator, and optionally contains (D) an organic solvent.

### Component (A)

Component (A) of the present invention is one or more type of siloxane compound selected from the abovementioned (a1) and (a2), and two or more types of siloxane compounds may be used. This component has an alkenyl group and can chemically react with the reactive functional group of component (B), and acts as a crosslinking agent in the composition.
(a1) a linear siloxane having at least two alkenyl groups and at least one aryl group in a molecule
(a2) a siloxane having at least two alkenyl groups in a molecule and having 8 or less silicon atoms

In order to ensure favorable affinity with component (B) described below, component (A) must satisfy either of the abovementioned conditions (a1) or (a2). Specifically, component (A) is (a1) an alkenyl group-containing siloxane compound having at least one aryl group in a molecule, or (a2) having 8 or fewer silicon atoms. A compound that satisfies both of these conditions can be used without any problems. More specifically, component (A) may be a siloxane compound that corresponds to either the siloxane compound (a1) or (a2) (for example, a “linear siloxane having at least two alkenyl groups in a molecule, having 8 or fewer silicon atoms, and having an aryl group” corresponds to both component (a1) and component (a2), and thus can be used without problem as component (A) of the present invention).

On the other hand, if the siloxane compound does not fall into either of the abovementioned (a1) or (a2), for example, if the number of silicon atoms in the siloxane compound exceeds 8 and the compound does not have a linear structure (for example, the structure is resinous or branched), it may not be possible to ensure favorable affinity with component (B). Furthermore, in the case of a siloxane compound that does not have an alkenyl group in a molecule, it is not possible to ensure reactivity with component (B).

Specific examples of linear siloxane compounds that fall into the category of (a1) above include 1,1,3-trimethyl-3-phenyl-1,3-divinyldisiloxane, 1,3-dimethyl-1,3-diphenyl-1,3-divinyldisiloxane, 1,1,5,5-tetramethyl-3,3-diphenyl-1,5-divinyltrisiloxane, 1,1,7,7-tetramethyl-3,3,5,5-tetraphenyl-1,7-divinyltetrasiloxane, dimethyl/methylphenylsiloxane copolymers terminated with dimethylvinylsilyl at both ends, dimethyl/diphenylsiloxane copolymers terminated with dimethylvinylsilyl at both ends, polymethylphenylsiloxane copolymers terminated with dimethylvinylsilyl at both ends, methylphenyl/methylvinylsiloxane copolymers terminated with trimethylsilyl at both ends, and the like.

Of the abovementioned compound group, component (A) is preferably (a1-1) a linear siloxane having at least two alkenyl groups in a molecule, and in which the molar fraction of aryl groups in all substitution groups on silicon atoms is 20% or more. These properties further improve affinity with component (B), contributing to improved toughness of a cured product obtained from the composition. Specifically, recommended examples of a preferred component (A) include 1,3-dimethyl-1,3-diphenyl-1,3-divinyldisiloxane, 1,1,5,5-tetramethyl-3,3-diphenyl-1,5-divinyltrisiloxane, 1,1,7,7-tetramethyl-3,3,5,5-tetraphenyl-1,7-divinyltetrasiloxane, dimethyl/methylphenylsiloxane copolymers terminated with dimethylvinylsilyl at both ends and having an aryl group molar fraction of 20% or more, dimethyl/diphenylsiloxane copolymers terminated with dimethylvinylsilyl at both ends and having an aryl group molar fraction of 20% or more, and polymethylphenylsiloxane copolymers terminated with dimethylvinylsilyl at both ends.

On the other hand, specific examples of siloxanes having 8 or less silicon atoms that fall into the category of (a2) above include 1,7-divinyl-1,1,3,3,5,5,7,7-octamethyltetrasiloxane, 1,3,5,7-tetramethyl-1,3,5,7-tetravinylcyclotetrasiloxane, methyltris(dimethylvinylsiloxy) silane, phenyltris(dimethylvinylsiloxy) silane, tetrakis(dimethylvinylsiloxy) silane, and the like.

Of the abovementioned compound group, component (A) is preferably (a2-1) a cyclic siloxane having at least two alkenyl groups in a molecule and having 8 or less silicon atoms. Furthermore, one desirable condition is that the boiling point under ambient pressure is 220° C. or higher. These properties improve affinity with component (B) and also contribute to improving the modulus of elasticity of a cured product obtained from the composition. Specifically, 1,3,5,7-tetramethyl-1,3,5,7-tetravinylcyclotetrasiloxane is recommended as a preferred component (A).

Therefore, the siloxane compound groups classified into the abovementioned categories (a1-1) and (a2-1) can be preferably used as component (A) of the present invention. Specifically, recommended examples thereof include 1,3-dimethyl-1,3-diphenyl-1,3-divinyldisiloxane, 1,1,5,5-tetramethyl-3,3-diphenyl-1,5-divinyltrisiloxane, 1,1,7,7-tetramethyl-3,3,5,5-tetraphenyl-1,7-divinyltetrasiloxane, dimethyl/methylphenylsiloxane copolymers terminated with dimethylvinylsilyl at both ends and having an aryl group molar fraction of 20% or more, dimethyl/diphenylsiloxane copolymers terminated with dimethylvinylsilyl at both ends and having an aryl group molar fraction of 20% or more, polymethylphenylsiloxane copolymers terminated with dimethylvinylsilyl at both ends, and 1,3,5,7-tetramethyl-1,3,5,7-tetravinylcyclotetrasiloxane. These compounds can be used alone or in combination of two or more types.

### Component (B)

Component (B) is at least one compound selected from aromatic polymers having a reactive functional group and cycloolefin polymers having a reactive functional group This component contributes to improving the heat resistance of a cured product obtained by heat-curing the present curable composition, and particularly to increasing the modulus of elasticity at a high temperature, and also contributes to reducing the relative dielectric constant by taking advantage of the properties of a low polarity skeleton thereof.

Component (B) may be an aromatic polymer, a cycloolefin polymer, or a mixture thereof, so long as a reactive functional group is provided. In other words, component (B) may be a single compound or a mixture of a plurality of compounds, and by using component (B) in combination with component (A), the physical properties of the cured product can be improved, the relative dielectric constant can be reduced, and low dielectric properties can be imparted. Note that a component (B) having an aromatic polymer as a basic skeleton and a component (B) having a cycloolefin polymer as a basic skeleton can be appropriately selected depending on the application, physical properties, and desired relative dielectric constant of the cured product. Moreover, a preferred embodiment of the present invention also includes adjusting the mixing ratio of components (B) having different basic skeletons to achieve desired properties.

### Aromatic Polymer Having Reactive Functional Group

There are no limitations on the position of the reactive functional group in the aromatic polymer having a reactive functional group of component (B), but from the perspective of favorable reaction controllability, the aromatic polymer having a reactive functional group at a molecular chain end is preferable. Herein, the aromatic polymer refers to a polymer with a main chain containing an aryl group and a heteroatom-containing group linking the aryl group, and specifically an ether group, thioether group, ester group, thioester group, amide group, imide group, urethane group, thiourethane group, urea group, thiourea group, acid anhydride group, or other linking group. Of these linking groups, the lower the polarity, the more preferable the linking group from the perspective of contributing to a reduction in the relative dielectric constant. Therefore, an ether bond is a recommended linking group. In other words, examples of preferred components (B) include polymers having an aryl group and ether bond as main structural units, and polyphenylene ether (PPE) is recommended as a preferred polymer. In particular, PPE having a reactive functional group at a molecular chain end is a particularly preferred polymer.

Herein, PPE is formed from repeating units including phenylene groups and ether bonds, but may contain a copolymerization component unit other than the phenylene ether unit structure within a range that does not impair a function and effect of the present invention. Specific examples of component (B) of the present invention include: PPE having a substitution group, such as poly(2,6-dimethyl-1,4-phenylene ether), poly(2-methyl-6-ethyl-1,4-phenylene ether), poly(2-methyl-6-phenyl-1,4-phenylene ether), poly(2,6-dichloro-1,4-phenylene ether), or the like; and PPE copolymers, such as copolymers of 2,6-dimethylphenol and other phenols (e.g., 2,3,6-trimethylphenol, 2-methyl-6-butylphenol, and the like), PPE copolymers obtained by coupling 2,6-dimethylphenol with biphenols or bisphenols, and the like.

The reactive functional group of aforementioned component (B) is preferably a functional group in which a reaction is accelerated by heating, similar to component (A), and specifically, is preferably one or more type of functional group selected from alkenyl groups and (meth)acrylate groups. Herein, preferred examples of the alkenyl group include alkenyl groups with 2 to 8 carbon atoms. Specific examples include vinyl groups, allyl groups, 1-butenyl groups, 1-pentenyl groups, 1-hexenyl groups, and styryl groups, with vinyl groups, allyl groups, and styryl groups being particularly preferable. Meanwhile, both an acrylate group and a methacrylate group can be applied as the (meth)acrylate group. In consideration of reactivity, acrylate groups are more preferable.

In other words, in the present invention, recommended examples of component (B) include: PPE having vinyl groups at both ends of a molecular chain; PPE having a vinyl group at one end of a molecular chain; PPE having allyl groups at both ends of a molecular chain; PPE having an allyl group at one end of a molecular chain; PPE having styryl groups at both ends of a molecular chain; PPE having a styryl group at one end of a molecular chain; PPE having acrylate groups at both ends of a molecular chain; PPE having an acrylate group at one end of a molecular chain; PPE having methacrylate groups at both ends of a molecular chain; and PPE having a methacrylate group at one end of a molecular chain. Of these, component (B) is preferably PPE having reactive functional groups at both ends of a molecular chain, and specifically, preferably PPE having styryl groups at both ends of a molecular chain, PPE having acrylate groups at both ends of a molecular chain, or PPE having methacrylate groups at both ends of a molecular chain. A widely used a modified PPE (product name: SA9000) terminated with a methacrylate group at an end, which is manufactured by Sabic Innovative Plastics, can also be used as component (B). There are no particular limitations on the molecular weight of the aromatic polymer having a reactive functional group of component (B), but it is recommended that the weight average molecular weight be 1,000 or more and 5,000 or less in terms of standard polystyrene, as measured by gel permeation chromatography (GPC). In particular, the weight average molecular weight is particularly preferably 1,000 or more and 3,000 or less. Due to this property, when heat-cured, a cured product with low brittleness and favorable mechanical strength can be obtained.

### Cycloolefin Polymer Having Reactive Functional Group

The component (B) may be a polymer having a cycloolefin ring structure as a basic skeleton, and a part or all thereof may be a cycloolefin polymer having a reactive functional group. Specifically, the cycloolefin polymer of component (B) is a (co) polymer having, as an essential structural unit, a repeating unit derived from a cyclic olefin, which has the reactive functional group described above in a molecule. A cycloolefin monomer (cyclic olefin compound) constituting the cycloolefin polymer (B) that can be used in the present invention is not particularly limited, and is a compound having a polymerizable carbon-carbon double bond that allows chain polymerization (metathesis ring-opening polymerization, addition polymerization, and the like) and having, as an alicyclic structure, a monocyclic ring, a polycyclic ring, a condensed polycyclic ring, a bridged ring, a polycyclic ring formed by combining these rings, or the like. The cycloolefin monomer constituting component (B) of the present invention may be a cyclic olefin monomer described in paragraphs to of WO 2006/0118261. Furthermore, the cycloolefin polymers that can be used in the present invention include those disclosed in Japanese Unexamined Patent Application 2015-067671, Japanese Unexamined Patent Application 2014-162172, Japanese Unexamined Patent Application 2015-160326, Japanese Unexamined Patent Application 2015-123671, Japanese Unexamined Patent Application 2015-123670, Japanese Unexamined Patent Application 2014-205727, Japanese Unexamined Patent Application 2014-177568, Japanese Unexamined Patent Application 2018-034422, Japanese Unexamined Patent Application 2018-035257, Japanese Unexamined Patent Application 2017-125176, Japanese Unexamined Patent Application 2017-125175, Japanese Unexamined Patent Application 2017-125174, and the like, and can be used without particular limitation. Cycloolefin polymers obtained by structures, monomers, and synthesis examples disclosed in these documents can be used as part or all of component (B) of the present invention.

Component (B) may contain an aromatic polymer having a reactive functional group and a cycloolefin polymer having a reactive functional group in a mixing ratio of 100:0 to 0:100. For example, from the perspective of further improving the dielectric properties while maintaining favorable heat resistance and thermal stability of the resulting cured product, prepreg, or printed circuit board, or improving the impregnation of a curable resin composition into a sheet-like fiber base material or the like when producing a prepreg, a cycloolefin polymer may be selected as component (B). Alternatively, from the perspective of the mechanical properties and low dielectric constant of the cured product, an aromatic polymer such as polyphenylene ether (PPE) having a reactive functional group at a molecular chain end may be selected as component (B).

The mixing ratio (parts by mass) of component (A) to component (B) in the thermosetting composition of the present invention is in the range of 10 to 90 parts by mass of (A) to 10 to 90 parts by mass of (B), where the sum of component (A) and component (B) is 100 parts by mass. The mixing ratio has a significant effect on the properties of the cured product, and thus the ratio is preferably designed to be within the abovementioned range depending on the application of the cured product. Specifically, the mechanical properties, and particularly the modulus of elasticity at high temperatures, depend on the type and amount of the reactive functional group in component (A), but tend to increase as the component (A)/component (B) ratio increases. On the other hand, the toughness of the cured product therefore depends on the concentration of alkenyl groups in component (A), and a cured product obtained from a compound with a low concentration of alkenyl groups tends to exhibit high toughness. Therefore, by optimizing the mixing ratio and the chemical structure of component (A), the mechanical properties and dielectric properties of the resulting cured product can be induced to fall within a desired region of physical properties.

### Combined Use of Other Organic Resins

The main agents in the thermosetting composition of the present invention are component (A) and component (B), but a reactive organic resin other than component (B) can be used in combination so long as a technical effect of the present invention is not impaired. For example, in the present invention, component (B) can be used in combination with (B′) one or more type of organic resin selected from epoxy resins, polyimide resins, liquid crystal polymers, maleimide resins (including so-called BT resins), and polybutadiene resins. These organic resins are optional components, and therefore, the amounts thereof to be used are not particularly limited. However, one or two or more types of organic resins may be and are preferably used in an amount of 0 to 500 parts by mass, 0 to 250 parts by mass, or 0 to 100 parts by mass with respect to 100 parts by mass of components (AB). Furthermore, in order to improve compatibility between these organic resins with component (A) and component (B), a compatibilizer (B″) selected from modified polyolefins, modified elastomers, compounds having a polar group and an unsaturated carbon bond capable of contributing to a polymerization reaction in a molecule, and the like may be included.

The epoxy resin may be one or more selected from phenol novolac epoxy resins, cresol novolac epoxy resins, bisphenol A epoxy resins, bisphenol F epoxy resins, bisphenol A novolac epoxy resins, bisphenol F novolac epoxy resins, brominated bisphenol A epoxy resins, brominated bisphenol F epoxy resins, hydrogenated bisphenol A epoxy resins, and other glycidyl ether epoxy resins, alicyclic epoxy resins, glycidyl ester epoxy resins, glycidyl amine epoxy resins, isocyanurate epoxy resins, epoxy resins having an alicyclic olefin structure or a fluorene structure, and the like. Note that from the perspective of further improving the mechanical strength of the resulting cured product, at least one resin selected from bisphenol A epoxy resins and bisphenol A novolac epoxy resins may be selected.

Examples of polyimide resins include those described in paragraphs to of Japanese Unexamined Patent Application 2009-120696, and can be obtained by reacting a tetracarboxylic acid anhydride, diimide, or monoimide (hereinafter abbreviated as tetracarboxylic acid anhydride or the like) with a diamine. The reaction of the tetracarboxylic acid anhydride or the like with the diamine can be performed by a generally known method, and commercially available products can also be used. Furthermore, the polyimide resin may be a linear polyimide.

The liquid crystal polymer is not particularly limited, and examples thereof include those described in paragraphs to of Japanese Unexamined Patent Application 2008-19400, which are melt-processable polymers capable of forming an optically anisotropic molten phase. The type of liquid crystal polymer is not particularly limited, but is preferably an aromatic polyester or an aromatic polyester amide, and may be a polyester partially containing an aromatic polyester or an aromatic polyester amide in the same molecular chain.

The maleimide resin is not particularly limited, and examples thereof include those described in paragraphs to of Japanese Unexamined Patent Application 2006-124494, which are maleimide resins obtained from a maleimide compound (X) having two or more maleimide groups in a molecule. Furthermore, the range of maleimide resins includes mixtures with triazine resins obtained by reacting the maleimide compound (X) with a cyanate ester compound (Y) (bismaleimide triazine resins (BT resins)).

Examples of the maleimide compound (X) include bis(4-maleimidophenyl) methane, 2,2-bis {4-(4-maleimidophenoxy)-phenyl}propane, bis(3,5-dimethyl-4-maleimidophenyl) methane, bis(3-ethyl-5-methyl-4-maleimidophenyl) methane, bis(3,5-diethyl-4-maleimidophenyl) methane, 2,2′-bis[4-(4-maleimidophenoxy)phenyl]propane, polyphenylmethane maleimide, m-phenylene bismaleimide, p-phenylene bismaleimide, 3,3′-dimethyl-5,5′-diethyl-4,4′-diphenylmethane bismaleimide, 4-methyl-1,3-phenylene bismaleimide, 4,4′-diphenylether bismaleimide, 4,4′-diphenylsulfone bismaleimide, 1,3-bis(3-maleimidophenoxy)benzene, 1,3-bis(4-maleimidophenoxy)benzene, 1,6′-bismaleimido-1,6-bismaleimidohexane, (2,2,4-trimethyl) hexane, 1,2-bismaleimidoethane, polytetramethylene oxide-bis(4-maleimidobenzoate), and the like.

The cyanate ester compound (Y) is not particularly limited so long as the cyanate ester compound has two or more cyanate groups in one molecule, and examples thereof include: cyanate ester compounds obtained by reacting cyanogen halide with 1,3- or 1,4-dicyanate benzene, 1,3,5-tricyanate benzene, 1,3-, 1,4-, 1,6-, 1,8-, 2,6- or 2,7-dicyanate naphthalene, 1,3,6-tricyanate naphthalene, 4,4-dicyanate biphenyl, bis(4-cyanate phenyl) methane, bis(3,5-dimethyl-4-cyanate phenyl) methane, 2,2-bis(4-cyanate phenyl) propane, 2,2-bis(3,5-dibromo-4-cyanate phenyl) propane, 2,2-bis(3,5-dimethyl-4-cyanatophenyl) propane, bis(4-cyanatephenyl) ether, bis(4-cyanatephenyl)thioether, bis(4-cyanatephenyl) sulfone, tris(4-cyanatephenyl)phosphite, tris(4-cyanatephenyl)phosphate, oligomers (novolak, hydroxyl group-containing thermoplastic resins (hydroxypolyphenylene ether, hydroxypolystyrene, hydroxypolycarbonate, and the like)), and the like; cyanate ester compounds obtained by reacting cyanogen halide with a polyfunctional phenol in which phenol is bonded via dicyclopentadiene; and the like.

The polybutadiene resin is not particularly limited, and examples thereof include 1,4-polybutadiene, 1,2-polybutadiene, modified polybutadiene terminated with a acrylate at an end, modified polybutadiene terminated with urethane methacrylate at an end, and the like.

### Component (C)

Component (C) is a thermal radical initiator that acts as a catalyst to accelerate a curing reaction by heating. Any compound that decomposes upon heating and generates free radical species can be used as component (C) of the present invention, regardless of a chemical structure thereof. Typically, organic peroxides that decompose to generate oxygen radicals and azo compounds that decompose to generate carbon radicals are well known, and either of these compound groups can be used alone or in combination of two or more types. Furthermore, an organic peroxide and an azo compound can be used in combination.

Known organic peroxides are broadly classified according to the chemical structures thereof into (I) diacyl peroxides, (II) peroxydicarbonates, (III) peroxyesters, (IV) peroxyketals, (V) dialkyl peroxides, (VI) hydroperoxides, and (VII) others. Specific examples of compounds classified as (I) include dibenzoyl peroxide and dilauroyl peroxide; a specific example of a compound classified as (II) includes di(2-ethylhexyl) peroxydicarbonate; specific examples of compounds classified as (III) include tert-butyl peroxyacetate and tert-butyl peroxylaurate; specific examples of compounds classified as (IV) include 1,1-di(tert-butylperoxy)cyclohexane and normal butyl-4,4-(tert-butylperoxy) valerate; specific examples of compounds classified as (V) include dicumyl peroxide, di-tert-butyl peroxide and 2,5-dimethyl-2,5-di(tert-butylperoxy) hexyne-3; and specific examples of compounds classified as (VI) include cumene hydroperoxide, diisopropylbenzene hydroperoxide, 1,1,3,3-tetramethylbutyl hydroperoxide and di-tert-butyl hydroperoxide. The compound is not limited thereto.

Known azo compounds are broadly classified according to the chemical structure thereof into (I) azonitriles, (II) azoesters, (III) azoamides, and (IV) others. Specific examples of compounds classified into (I) include 2,2-azobis(2-methylbutyronitrile), 1,1-azobis(cyclohexane-1-carbonitrile), and 2,2-azobis(isobutyronitrile); a specific example of a compound classified into (II) includes dimethyl-2,2-azobis(isobutyrate); specific examples of compounds classified into (III) include 2,2-azobis[N-(2-propenyl)-2-methylpropionamide] and 2,2-azobis(N-butyl-2-methylpropionamide); and a specific example of a compound classified into (IV) includes 2,2-azobis[2-(2-imidazolin-2-yl) propane]. The compound is not limited thereto.

The activity of the abovementioned compound group is defined by the half-life temperature associated with decomposition in the temperature range used for the reaction, and usually, the 10-hour half-life temperature (T10h) and the 1-minute half-life temperature (Tim) are widely used. In the present invention, in consideration of the temperature range when the thermosetting composition to be described later is cured, a compound that satisfies at least one of the conditions of Tioh being 110° C. or higher and Tim being 170° C. or higher is preferably used as component (C). When two or more types of compounds are used in combination, at least one of the compounds preferably satisfies this condition.

In view of the conditions above, component (C) of the present invention preferably contains at least one compound selected from the group of compounds broadly classified into dialkyl peroxides and hydroperoxides. Specific examples of compounds that can be preferably used include dicumyl peroxide, di-tert-butyl peroxide, 2,5-dimethyl-2,5-di(tert-butylperoxy) hexyne-3, di(2-tert-butylperoxyisopropyl)benzene, cumene hydroperoxide, diisopropylbenzene hydroperoxide, 1,1,3,3-tetramethylbutyl hydroperoxide, di-tert-butyl hydroperoxide, and paramenthane hydroperoxide.

The amount of component (C) of the present invention is an amount of 0.1 to 5 parts by mass with respect to 100 parts by mass of the total of components (A) and (B). The amount is preferably 0.1 to 3 parts by mass, and more preferably 0.3 to 1 part by mass. If the amount of the component is less than 0.1 parts by mass, the time required for the curing reaction of the thermosetting composition to be described later is longer, and there is a concern that the degree of curing will be non-uniform in a cured product. On the other hand, if the amount exceeds 5 parts by mass, there is a high possibility that component (C) will remain even after the curing reaction is complete, which will have an adverse effect on the heat resistance, mechanical properties, and the like of the cured product.

### Component (D)

Component (D) is an organic solvent and serves as an auxiliary agent for mixing components (A), (B), and (C) to prepare a uniform curable composition. By removing component (D) from the system after mixing the raw materials that constitute the curable composition, a uniform composition with excellent transparency can be prepared. In addition to the abovementioned objectives, component (D) also functions to adjust the film thickness of a coating film derived from the curable composition. This component is an optional component, but in consideration of the abovementioned functions, the component is practically preferably used at a stage of mixing another component. As such an organic solvent, any organic solvent that has been conventionally blended in various organopolysiloxane-based curable compositions can be used without particular limitation.

Examples of preferred organic solvents include: ethylene glycol monomethyl ether, ethylene glycol monoethyl ether, ethylene glycol mono-n-propyl ether, ethylene glycol mono-n-butyl ether, diethylene glycol monomethyl ether, diethylene glycol monoethyl ether, diethylene glycol mono-n-propyl ether, diethylene glycol mono-n-butyl ether, propylene glycol monomethyl ether, propylene glycol monoethyl ether, propylene glycol mono-n-propyl ether, propylene glycol mono-n-butyl ether, dipropylene glycol monomethyl ether, dipropylene glycol monoethyl ether, dipropylene glycol mono-n-propyl ether, dipropylene glycol mono-n-butyl ether, and other (poly)alkylene glycol monoalkyl ethers; ethylene glycol monomethyl ether acetate, ethylene glycol monoethyl ether acetate, diethylene glycol monomethyl ether acetate, diethylene glycol monoethyl ether acetate, propylene glycol monomethyl ether acetate (PGMEA), propylene glycol monoethyl ether acetate, and other (poly)alkylene glycol monoalkyl ether acetates; diethylene glycol dimethyl ether, diethylene glycol methyl ethyl ether, diethylene glycol diethyl ether, and other ethers; methyl ethyl ketone, methyl isobutyl ketone, cyclohexanone, 2-heptanone, 3-heptanone, 4-heptanone, 5-methyl-3-heptanone, 2,4-dimethyl-3-pentanone, 2,6-dimethyl-4-heptanone, and other ketones; methyl 2-hydroxypropionate, ethyl 2-hydroxypropionate, and other lactic acid alkyl esters; ethyl 2-hydroxy-2-methylpropionate, methyl 3-methoxypropionate, ethyl 3-methoxypropionate, methyl 3-ethoxypropionate, ethyl 3-ethoxypropionate, ethoxyethyl acetate, ethyl hydroxyacetate, methyl 2-hydroxy-3-methylbutanoate, 3-methoxybutyl acetate, 3-methyl-3-methoxybutyl acetate, 3-methyl-3-methoxybutyl propionate, ethyl acetate, n-propyl acetate, i-propyl acetate, n-butyl acetate, i-butyl acetate, n-pentyl formate, i-pentyl acetate, n-butyl propionate, ethyl butyrate, n-propyl butyrate, i-propyl butyrate, n-butyl butyrate, methyl pyruvate, ethyl pyruvate, n-propyl pyruvate, methyl acetoacetate, ethyl acetoacetate, ethyl 2-oxobutanoate, and other esters; toluene, xylene, mesitylene, cumene, propylbenzene, diethylbenzene, 1,3-diisopropylbenzene, and other aromatic hydrocarbons; and anisole, phenetole, 2-methoxytoluene, 3-methoxytoluene, 4-methoxytoluene, 3,4-dimethoxytoluene, 1,4-bis(methoxymethyl)benzene, and other aromatic ethers. Component (D) may be used alone, or a plurality of components (D) may be used in combination, in consideration of miscibility with components (A) to (C).

The amount of component (D) is an amount of 0 to 1,000 parts by mass with respect to 100 parts by mass of the total of components (A) to (C) of the present invention. In other words, although component (D) does not have to be included in the present thermosetting composition, this component is preferably included in order to efficiently prepare a uniform and transparent curable composition. A preferred amount used may be 10 to 1,000 parts by mass, and more preferably 10 to 200 parts by mass, with respect to 100 parts by mass of the total of components (A) to (C).

### Other Additives

The thermosetting composition of the present invention may contain further additives in addition to the abovementioned components (A) to (D), if desired. Examples of additives include, but are not limited to, those described below.

### Crosslinking Agent

The thermosetting composition of the present invention may further contain a component capable of chemically reacting with component (B) as a crosslinking agent in order to control crosslinking density and adjust physical properties, and particularly the mechanical properties and dielectric properties, of the resulting cured product, or to adjust the efficiency of the curing reaction. Preferred examples of such components include silicon-free compounds. In consideration of affinity with component (A), a compound that has a refractive index (nD) of 1.45 or more and may or may not have an aryl group is preferred.

The silicon-free compound preferably used as a crosslinking agent is preferably a compound having at least two polymerizable double bonds in a molecule. Specific examples thereof include triallyl isocyanurate and other trialkenyl isocyanurate compounds, triallyl cyanurate and other trialkenyl cyanurate compounds, polyfunctional (meth)acrylate compounds having two or more (meth)acrylate groups in a molecule, divinylbenzene and other multivinylaryl compounds, 4,4′-bismaleimide diphenylmethane and other polyfunctional maleimide compounds having two or more maleimide groups in a molecule, and the like.

There are no significant limitations on the amount of the crosslinking agent added to the thermosetting composition of the present invention, but the amount is preferably in the range of 0.5 to 10 parts by mass, 1 to 10 parts by mass, or 1 to 5 parts by mass with respect to 100 parts by mass of component (A).

### Adhesion-Imparting Agent

An adhesion-imparting agent can be added to the thermosetting composition of the present invention to improve adhesion and close-fitting properties to a base material in contact with the composition. When the curable composition of the present invention is used for applications such as coating agents, sealing materials, and the like that require adhesion or close-fitting properties to a base material, an adhesion-imparting agent is preferably added to the thermosetting composition of the present invention. An arbitrary known adhesion-imparting agent can be used, so long as the adhesion-imparting agent does not interfere with a curing reaction of the composition of the present invention.

Examples of the adhesion-imparting agent that can be used in the present invention include: organosilanes having a trialkoxysiloxy group (such as a trimethoxysiloxy group or a triethoxysiloxy group) or a trialkoxysilylalkyl group (such as a trimethoxysilylethyl group or triethoxysilylethyl groups) and a hydrosilyl group or an alkenyl group (such as a vinyl group or an allyl group), or organosiloxane oligomers having a linear structure, branched structure, or cyclic structure with approximately 4 to 20 silicon atoms; organosilanes having a trialkoxysiloxy group or a trialkoxysilylalkyl group and a methacryloxyalkyl group (such as a 3-methacryloxypropyl group), or organosiloxane oligomers having a linear structure, branched structure, or cyclic structure with approximately 4 to 20 silicon atoms; organosilanes having a trialkoxysiloxy group or a trialkoxysilylalkyl group and an epoxy group-bonded alkyl group (such as a 3-glycidoxypropyl group, a 4-glycidoxybutyl group, a 2-(3,4-epoxycyclohexyl)ethyl group, or a 3-(3,4-epoxycyclohexyl) propyl group), or organosiloxane oligomers having a linear structure, branched structure, or cyclic structure with approximately 4 to 20 silicon atoms; organic compounds having two or more trialkoxysilyl groups (such as trimethylsilyl groups or triethoxysilyl groups); reaction products of aminoalkyltrialkoxysilane and epoxy group-bonded alkyltrialkoxysilane, and epoxy group-containing ethyl polysilicate. Specific examples thereof include vinyl trimethoxysilane, allyl trimethoxysilane, allyl triethoxysilane, hydrogen triethoxysilane, 3-glycidoxypropyl trimethoxysilane, 3-glycidoxypropyl triethoxysilane, 2-(3,4-epoxycyclohexyl)ethyl trimethoxysilane, 3-methacryloxypropyl trimethoxysilane, 3-methacryloxypropyl triethoxysilane, 1,6-bis(trimethoxysilyl) hexane, 1,6-bis(triethoxysilyl) hexane, 1,3-bis[2-(trimethoxysilyl)ethyl]-1,1,3,3-tetramethyldisiloxane, reaction products of 3-glycidoxypropyl triethoxysilane and 3-aminopropyl triethoxysilane, condensation reaction products of a methylvinyl siloxane oligomer blocked with a silanol group and a 3-glycidoxypropyl trimethoxysilane, condensation reaction products of a methylvinyl siloxane oligomer blocked with a silanol group and a 3-methacryloxypropyl triethoxysilane, and tris(3-trimethoxysilylpropyl) isocyanurate.

The amount of the adhesion-imparting agent to be added to the thermosetting composition of the present invention is not particularly limited. However, it does not promote curing properties of the curable composition or discoloration of a cured product, and therefore, the amount is preferably within a range of 0.01 to 5 parts by mass, or within a range of 0.01 to 2 parts by mass, with respect to 100 parts by mass total of components (A) to (C).

### Additional Optional Additives

In addition to or instead of the crosslinking agent and adhesion-imparting agent described above, another additive may be added to the thermosetting composition of the present invention or the cured product thereof, if desired. Examples of additives that can be used include flame retardants, heat stabilizers, weather stabilizers, antistatic agents, slip agents, antiblocking agents, antifogging agents, lubricants, dyes, pigments, natural oils, synthetic oils, waxes, organic or inorganic fillers, leveling agents, silane coupling agents not included in the abovementioned adhesion-imparting agents, heat ray-absorbing agents, antioxidants, polymerization inhibitors, fillers (reinforcing fillers, insulating fillers, thermally conductive fillers, and other functional fillers), glass cloth and other fibrous reinforcing materials, and the like. Furthermore, a thixotropy imparting agent may also be added to the composition of the present invention if necessary, particularly when used as a sealing agent. Furthermore, thermoplastic resins, thermosetting resins, and the like other than the abovementioned components (A), (B), (B′), and (B″) can be blended to an extent that does not impair the object of the present invention, and the blending ratio thereof is an appropriate amount.

### Method for Molding and Curing Thermosetting Composition

The thermosetting composition of the present invention usually contains the organic solvent of component (D), but the cured product obtained from this composition preferably does not contain component (D). Therefore, a thermosetting composition containing components (A) to (D) is preferably prepared in advance, and the component (D) is preferably removed to prepare a thermosetting composition containing components (A) to (C). In other words, in terms of processing, component (D) is preferably mixed with components (A) to (C) to obtain a uniform and transparent composition containing components (A) to (C), and then removed from the composition.

Specifically, a method for molding and curing a thermosetting composition, which includes at least the following steps (i) and (ii), is recommended.
(i) A step for removing component (D) from the thermosetting composition of the present invention (provided that the amount of component (D) is not 0 parts by mass) at a temperature in the range of approximately 80 to 100° C. under ambient pressure or reduced pressure.
(ii) A step for, following step (i), curing the thermosetting composition at a temperature of 150° C. or higher and then processing into a desired shape.

As described above, an additive may be added to or impregnated into the thermosetting composition of the present invention, if necessary. When the prepared composition has sufficient fluidity, the composition can be coated to a desired base material or can be molded by a method of pouring the composition into a mold having a desired shape, or the like. On the other hand, if the composition does not have sufficient fluidity, the composition can be processed into a desired shape by a method such as press molding or the like. The fluid or non-fluid thermosetting composition molded thereby is in an uncured state, and can be heat-cured in the subsequent step (ii) to obtain a cured product.

In step (i), the organic solvent of component (D) is removed, by a commonly known method, from the thermosetting composition molded by the aforementioned method. Therefore, the thermosetting composition used in the present manufacturing method is a composition containing the organic solvent of component (D).

The method for removing component (D) in step (i) is not particularly limited, and specific examples of methods for removing component (D) under ambient pressure include heating on a hot plate, heating in an oven, heating in a pressing machine, and the like. Meanwhile, examples of methods for removing component (D) under reduced pressure include heating in a vacuum oven, heating in a vacuum pressing machine, and the like. The temperature range for this is recommended to be approximately 80 to 100° C. More specifically, the temperature range is preferably such that the composition is hardly thermally cured. On the other hand, the organic solvent is preferably completely removed in this step, but it is practically acceptable for a small amount of the organic solvent (D) to remain, for example, about 0.1 to 10 parts by mass or less with respect to 100 parts by mass of the total of components (A) to (C).

In step (ii), the aforementioned thermosetting composition prepared above, which contains almost no component (D), is thermally cured at a temperature of 150° C. or higher while maintaining a desired shape. This step can be performed under ambient pressure, but if step (i) is performed under reduced pressure, the temperature can be raised in this state and the process can proceed to step (ii), which can then be performed under reduced pressure. Furthermore, if component (D) remains at the end of step (i), step (ii) can be and is preferably performed under reduced pressure. In consideration of the glass transition temperature of component (B), it is strongly recommended that the temperature in this step be 150° C. or higher, but temperature can be adjusted appropriately taking into consideration the half-life temperature of component (C) described above. Practically, the temperature may be in the range of 150 to 300° C., 150 to 270° C., or 150 to 250° C. Furthermore, the time required for step (ii) (curing time) is usually 1 to 5 hours. Note that during curing, curing can be and is preferably performed in two stages, for example, by changing the temperature conditions from low to high.

The present invention also encompasses a cured product obtained from the thermosetting composition containing the abovementioned components (A) to (C).

### Prepreg

On the other hand, by impregnating the present thermosetting composition (provided that the amount of component (D) is not 0 parts by mass) with a fibrous reinforcing material and then removing component (D), an uncured composition, which is usually called a prepreg, is obtained, the main components of which are the fibrous reinforcing material and at least one compound selected from reactive branched organopolysiloxanes, aromatic polymers having a reactive functional group, and cycloolefin polymers having a reactive functional group. The present invention also encompasses the prepreg. The resulting prepreg can be converted into a cured product containing a fibrous reinforcing material by subjecting the prepreg to the abovementioned heat-curing step. The amount of the fibrous reinforcing material herein is usually 30 to 200 parts by mass, and preferably 40 to 150 parts by mass, with respect to 100 parts by mass of the total of components (A) to (C).

Furthermore, the present invention also encompasses a high-frequency circuit board including a laminate in which one or more prepreg prepared by the aforementioned method are laminated.

More specifically, the prepreg may be formed by combining the thermosetting composition according to the present invention (provided that the amount of component (D) is not 0 parts by mass) with a sheet-like fiber base material. The method for manufacturing the prepreg is not particularly limited, and various known methods can be applied. An example thereof is a method including a step for impregnating a sheet-like fiber base material with the thermosetting composition containing the abovementioned component (D) to obtain an impregnated body, and a step for heating the obtained impregnated body to remove a solvent included in varnish.

Impregnation of the sheet-like fiber base material with the thermosetting composition can be performed, for example, by coating the thermosetting composition containing a prescribed amount of component (D) to the sheet-like fiber base material by a known method, such as spray coating, dip coating, roll coating, curtain coating, die coating, slit coating, or the like, and if necessary, placing a protective film thereon and pressing the film from an upper side by a roller or the like. Furthermore, the step for heating the impregnated body to dry the solvent included in the thermosetting composition containing abovementioned component (D) is not particularly limited, and examples thereof include: a batch method for drying in air or nitrogen using a blower dryer; a continuous method for drying by passing through a heating furnace; and the like. For example, the thermosetting composition containing component (D) is impregnated into a sheet-like fiber base material, and the resulting impregnated body is heated to a prescribed temperature, whereby the solvent (=component (D)) included in the composition evaporates, and a prepreg is obtained.

Fibers constituting the sheet-like fiber base material that can be used in the prepreg according to the present invention are not particularly limited, and examples thereof include: PET (polyethylene terephthalate) fibers, aramid fibers, polyamide (nylon) fibers, liquid crystal polyester fibers, and other organic fibers; glass fibers, carbon fibers, alumina fibers, tungsten fibers, molybdenum fibers, titanium fibers, steel fibers, boron fibers, silicon carbide fibers, silica fibers, and other inorganic fibers; and the like. Of these, organic fibers and glass fibers are preferred, and aramid fibers, liquid crystal polyester fibers, and glass fibers are particularly preferred. As the glass fiber, fibers such as E-glass, NE-glass, S-glass, D-glass, H-glass, T-glass, and the like can be suitably used.

Impregnation of the sheet-like fiber base material with the thermosetting composition containing component (D) is performed, for example, by immersion or coating. Impregnation may be repeated a plurality of times as needed. These sheet-like fiber base materials can be used alone or in combination of two or more. The amount thereof used is selected appropriately as desired, but is usually in the range of 30 to 200 mass %, preferably 40 to 150 mass %, and more preferably 40 to 120 mass % of the prepreg or laminate body. Within this range, the dielectric properties and mechanical strength of the resulting laminate body are well balanced, which is preferable.

The thickness of the prepreg according to the present invention is appropriately selected according to the intended use, but is usually 0.001 to 10 mm, preferably 0.005 to 1 mm, and more preferably 0.01 to 0.5 mm. Within this range, the formability during lamination and properties such as mechanical strength, toughness, and the like of the laminate body obtained by curing are sufficiently exhibited, which is preferable.

The prepreg according to the present invention may be formed into a metal-clad laminated plate by laminating a metal foil on at least one surface thereof and then heat-curing the prepreg by a laminating press or the like. Examples of metal foils include copper foil, aluminum foil, nickel foil, gold foil, silver foil, stainless steel foil, and the like.

### Application

The thermosetting composition of the present invention makes use of the dielectric properties of the cured product obtained after curing and is useful as a material for forming an insulating layer constituting various articles, particularly electronic devices and electric devices, and particularly as an insulating material for a circuit board of electric and electronic devices that utilize high frequency regions. Furthermore, the thermosetting composition of the present invention can also be used as an insulating coating agent composition, taking advantage of the favorable coating properties thereof.

The present invention is further described below on the basis of Examples, but the present invention is not limited to the Examples below.

### EXAMPLES

The preparation and evaluation of the thermosetting composition of the present invention, and the preparation and evaluation of the cured product thereof will be described in detail with reference to examples.

### Preparation of Thermosetting Composition and Cured Product

An aromatic polymer (b) having a prescribed amount of a reactive functional group, a thermal radical initiator (c), and toluene (d) in an amount equal to the mass of the aromatic polymer having a reactive functional group were added to a siloxane compound (a) having at least two alkenyl groups in a molecule to prepare a curable composition in the form of a homogeneous toluene solution. Using a rotary evaporator, 90% or more of the toluene in the solution was removed to prepare a transparent, highly concentrated varnish. The varnish was interposed between two polyimide films, and the toluene was completely removed in a vacuum press set at 100° C. for over 3 hours. The press was heated to 200° C. and held for 2 hours, then further heated to 220° C. and held for 2 hours, to obtain a light brown cured product having a thickness of approximately 0.5 mm.

### Appearance of Thermosetting Composition

The thermosetting composition (high-concentration varnish) was visually observed to judge the appearance including transparency.

### Mechanical Properties of Cured Product: Molding Processability

The practical toughness of the cured product was evaluated on the following three-point scale in light of the presence or absence of cracks in the cured product sheet prepared by the method and the shape retention ability thereof against stress when peeled from the polyimide (PI) film.
A: No cracks were observed, and shape retention ability was favorable when peeled from the PI film.
B: There were some cracks, and cracks occurred when peeled from the PI film.
C: Sheet cracked when peeled from the PI film, making it difficult to prepare a uniform test piece.

### Mechanical Properties of Cured Product: Tensile Modulus of Elasticity and Glass Transition Temperature

A test piece having a length of approximately 50 mm and a width of approximately 5 mm was cut out from the cured product sheet prepared by the method above to prepare a test piece for measurement. Using a dynamic viscoelasticity measuring device RSA-G2 manufactured by TA Instruments, the dynamic viscoelasticity was measured in tension mode under the following conditions, and the storage elastic modulus (E′: MPa) and glass transition temperature (Tg: ° C.) were determined.
Measurement conditions: Frequency: 1 Hz, strain: 0.1%, heating rate: 3° C./min

### Mechanical Properties of Cured Product: Elongation at Break, Strength at Break, and Toughness

Test pieces similar to those used in the dynamic viscoelasticity measurement were prepared from the cured product sheet prepared by the method above. The test piece was elongated at 25° C. and a tensile rate of 5 mm/min using an Autograph AGS-X manufactured by Shimadzu Corporation, and the elongation at break and strength at break were recorded. The toughness (KJ/m³) was calculated by integrating the area under the stress-strain curve to determine the stress value over every elongation of 0.004%.

### Dielectric Constant and Dielectric Loss Tangent

A test piece having a length of approximately 80 mm and a width of approximately 1.5 mm was cut out from the cured product sheet prepared by the method above to prepare a test piece for measurement. The measurement test piece was placed in an oven at 80° C. and dried for 1 hour. The relative dielectric constant (Dk) and dielectric loss tangent (Df) at 10 GHz were measured by a cavity resonance method using a network analyzer N5222B manufactured by Keysight Technologies, Inc. and a cavity resonator (CP531) manufactured by Kanto Electronics Application & Development Inc, in an environment of 23° C.±2° C. and a relative humidity of 50±5%.

### Examples and Comparative Examples

Using the components below, thermosetting compositions having the compositions shown in Table 1 (parts by mass, excluding toluene as a solvent) were prepared. In the component A, “Me”, “Vi”, and “Ph” represent a methyl group, a vinyl group, and a phenyl group, respectively.
(A-1): Siloxane expressed by (ViMe₂SiO)₂SiPh₂
(A-2): Siloxane expressed by (ViMe₂SiO)₃SiPh
(A-3): Linear polysiloxane expressed by ViMe₂Si(OSiMePh)ₙOSiMe₂Vi (average degree of polymerization n: 28)
(A-4): Siloxane expressed by (ViMeSiO)₄
(A-5): Siloxane expressed by (ViMezSiO)₄Si
(A-6)*: Linear polysiloxane expressed by HO(ViMeSiO)ₙH (average degree of polymerization n: 12)
(A-7)*: Triallyl isocyanurate (manufactured by FUJIFILM Wako Pure Chemical Corporation)
(A-8)*: Polybutadiene (B-1000, manufactured by Nippon Soda Co., Ltd.)
(B-1): Modified polyphenylene ether resin terminated with methacrylate at both ends (SA9000, manufactured by SABIC)
(C-1): Di(2-t-butylperoxyisopropyl)benzene (Perbutyl P, manufactured by NOF Corporation)
*(A-6) to (A-8) are main agents for comparative experiments.

TABLE 1

| | Example | Example | Example | Example | Example | Example | Comparative | Comparative | Comparative | Comparative |
|---|---|---|---|---|---|---|---|---|---|---|
| Component | 1 | 2 | 3 | 4 | 5 | 6 | example 1 | example 2 | example 3 | example 4 |
| (A-1) | 25 | | | | | | | | | |
| (A-2) | | 25 | | | | | | | | |
| (A-3) | | | 25 | | | | | | | |
| (A-4) | | | | 25 | 43 | | | | | |
| (A-5) | | | | | | 25 | | | | |
| (A-6)* | | | | | | | 25 | | | |
| (A-7)* | | | | | | | | 25 | | |
| (A-8)* | | | | | | | | | 43 | |
| (B-1) | 75 | 75 | 75 | 75 | 57 | 75 | 75 | 75 | 57 | 100 |
| (C-1) | 3 | 3 | 3 | 3 | 3 | 3 | 3 | 3 | 3 | 3 |
| Total | 103 | 103 | 103 | 103 | 103 | 103 | 103 | 103 | 103 | 103 |
| Appearance | Trans- | Trans- | Trans- | Trans- | Trans- | Trans- | Opaque | Trans- | Opaque | Trans- |
| of thermo- | parent | parent | parent | parent | parent | parent | | parent | | parent |
| setting | | | | | | | | | | |
| composition | | | | | | | | | | |
| Tg | 203 | 222 | 190 | 234 | 237 | 231 | 216 | 233 | 233 | 218 |
| Modulus of | 11 | 16 | 12 | 32 | 67 | 50 | 35 | 149 | 64 | 8 |
| elasticity at | | | | | | | | | | |
| Tg + 30° C. | | | | | | | | | | |
| Dk | — | — | 2.50 | 2.38 | — | — | — | 2.50 | — | 2.44 |
| Df | — | — | 0.0029 | 0.0052 | — | — | — | 0.0052 | — | 0.0072 |
| Molding | A | A | A | A | A | A | C | C | C | A |
| processability | | | | | | | | | | |

As shown in Table 1, the thermosetting compositions of the present invention exhibited high transparency and also had favorable molding processability. It was confirmed that cured products obtained from the compositions had a high glass transition temperature of 190° C. or higher, had excellent heat resistance, and allowed for adjustment of physical properties over a wide range. Meanwhile, the cured products obtained from the compositions exhibited high toughness, with the toughness of the cured products obtained in Examples 1 and 3 being 73 and 91 KJ/m³, respectively. Furthermore, the dielectric properties were also favorable. In particular, the cured product made from a linear organopolysiloxane containing aryl groups exhibited an extremely low dielectric loss tangent, suggesting that the product would be useful as an insulating material for a circuit board in electrical and electronic devices that utilize high frequency regions.

On the other hand, it was found that a composition containing triallyl isocyanurate, which is a crosslinking agent widely used industrially (Comparative Example 2), had insufficient molding processability and a resulting cured product had very low toughness. Furthermore, it was confirmed that compositions containing similarly well-known high molecular weight crosslinking agents (Comparative Examples 1 and 3) were opaque and had insufficient molding processability due to inferior compatibility between components. Furthermore, a cured product obtained from a composition that did not contain the specific organopolysiloxane serving as a crosslinking component (Comparative Example 4) did not have a sufficiently high modulus of elasticity at a high temperature, and the dielectric loss tangent was a relatively high value.

### Synthesis Example: Synthesis of Cycloolefin Polymer (B-2)

A glass reaction container, in which air has been thoroughly purged with nitrogen, is charged with the following, in order, using an injector: 225 mL of dicyclopentadiene (containing approximately 10% cyclopentadiene trimer); 0.54 g of diethylaluminum chloride; 0.99 g of a 1,3-dichloro-2-propanol dicyclopentadiene solution (70% concentration); 1.9 mL of a tridodecylammonium molybdate dicyclopentadiene solution (0.6 mol/L); and 0.84 mL of a benzylidenebis(tricyclohexylphosphine) ruthenium dichloride dichloromethane solution (8.2% concentration). The mixture is then vigorously stirred for 10 seconds. This reaction solution is preheated to 60° C., poured into a U-shaped resin spacer (thickness: 5 mm) designed to have an internal volume of 20×20×0.5 cm³, and press-molded for 5 minutes to obtain poly(dicyclopentadiene).

### Example VII

A thermosetting composition was obtained in the same manner as in Example 1, except that component (B-1) in Example 1 was replaced with the same mass of (B-2) poly(dicyclopentadiene) obtained by the abovementioned Synthesis Example. A cured product obtained by curing the thermosetting composition in the same manner as in Example 1 is expected to have favorable dielectric properties, as well as excellent physical strength, such as elasticity, molding processability, and the like.

1. A thermosetting composition, comprising
(A) 10 to 90 parts by mass of one or more type of siloxane compound selected from the following (a1) and (a2):
(a1) a linear siloxane having at least two alkenyl groups and at least one aryl group in a molecule; and
(a2) a siloxane having at least two alkenyl groups in a molecule and having 8 or less silicon atoms;
(B) 10 to 90 parts by mass of at least one compound selected from aromatic polymers having a reactive functional group and cycloolefin polymers having a reactive functional group, provided that the sum of component (A) and component (B) is 100 parts by mass; and
(C) a thermal radical initiator at an amount of 0.1 to 5 parts by mass with respect to 100 parts by mass of the total of components (A) and (B).

2. The thermosetting composition according to claim 1, wherein component (B) is a polyphenylene ether having a reactive functional group at a molecular chain end.

3. The thermosetting composition according to claim 1, wherein component (B) is a polyphenylene ether having one or more type of a reactive functional group selected from alkenyl groups and (meth)acrylate groups, at a molecular chain end.

4. The thermosetting composition according to claim 1, wherein component (A) is (A) one or more type of siloxane compound selected from the following (a1-1) and (a2-1):
(a1-1) a linear siloxane having at least two alkenyl groups in a molecule, and in which the molar fraction of aryl groups in all substitution groups on silicon atoms is 20% or more;
(a2-1) a cyclic siloxane having at least two alkenyl groups in a molecule and having 8 or less silicon atoms.

5. The thermosetting composition according to claim 1, further comprising:
(D) an organic solvent.

6. A cured product of the thermosetting composition according to claim 1.

7. A prepreg, comprising:
a cured product of the thermosetting composition according to claim 1; and
a fibrous reinforcing material.

8. A high-frequency circuit board, comprising a laminate of one or more of the prepreg according to claim 7.

9. A method for curing and molding the thermosetting composition according to claim 5, the method comprising the following steps:
(i) removing component (D) from the thermosetting composition at a temperature in the range of approximately 80 to 100° C. under ambient pressure or reduced pressure; and following step (i)
(ii) curing the thermosetting composition at a temperature of 150° C. or higher and then processing into a desired shape.

10. A method for manufacturing a prepreg, the method comprising: impregnating the thermosetting composition according to claim 5 with a fibrous reinforcing material, then removing component (D) and curing the thermosetting composition.
